(19) United States
(12) Patent Application Publication
(10) Pub. No.: US 2025/0392100 A1
(43) Pub. Date: Dec. 25, 2025

(54) SEMICONDUCTOR LASER

(71) Applicant: Lumentum Operations LLC, San Jose, CA (US)

(72) Inventors: Ryosuke HATAI, Sagamihara (JP); Kouji NAKAHARA, Tokyo (JP); Atsushi NAKAMURA, Komoro (JP)

(21) Appl. No.: 18/960,911

(22) Filed: Nov. 26, 2024

(30) Foreign Application Priority Data
Jun. 24, 2024 (JP) 2024101044
Sep. 25, 2024 (JP) 2024166497

(51) Int. Cl. H01S 5/12; H01S 5/10; H01S 5/22

(52) U.S. Cl. CPC H01S 5/1206; H01S 5/1014; H01S 5/22

(57) ABSTRACT

To provide a semiconductor laser excellent in high output characteristic and single mode oscillation, the semiconductor laser includes a substrate, an active layer, a cladding layer including a first grating layer having a first grating structure and a second grating layer having a second grating structure, and an electrode. The active layer and the cladding layer form a mesa structure, and the mesa structure includes first and second reflection regions forming a resonator in a direction in which the mesa structure extends. The second grating structure is formed in the first reflection region, and any one of the first grating structure or the second grating structure is formed in the second reflection region. A normalized coupling coefficient of the first reflection region is larger than that of the second reflection region. Mesa widths in the first reflection region and the second reflection region are different from each other.

### CROSS-REFERENCE TO RELATED APPLICATIONS

This Patent Application claims priority to Japan Patent Application No. 2024-166497,filed on Sep. 25, 2024, and to Japan Patent Application No. 2024-101044, filed on Jun. 24, 2024. The disclosures of the prior Applications are considered part of and is incorporated by reference into this Patent Application.

### TECHNICAL FIELD

The present disclosure relates generally to a semiconductor laser.

### BACKGROUND

Semiconductor lasers are widely used as a light source to be used in optical communications. A distributed feedback semiconductor laser (DFB laser) is one type of a semiconductor laser. A DFB laser can include a grating. Further, there can be a structure in which a phase shift region is included in the grating for characteristic improvement. A stable single-wavelength operation can be obtained by forming an anti-reflection film (or a low-reflection film) on both facets of the semiconductor laser and arranging a x-shift region in the grating. A reflectance with respect to a Bragg-reflected light beam can be changed between the front and the rear of the phase shift region so that output from one facet is increased.

### SUMMARY

Often, it is preferred that a DFB laser have high output power and oscillate at only a single wavelength. There can be a DFB laser in which a grating structure is removed at a constant period. A region from which the grating structure is removed and a region from which the grating structure is not removed are different in reflectance with respect to the Bragg wavelength, and a light output intensity from a facet on a side on which the grating structure is removed can consequently be increased. However, the region in which the grating structure is arranged and the region in which the grating structure is not arranged are different in effective refractive index, and reflection and scattering of a light beam may be induced at a boundary therebetween. This may cause a high output characteristic to deteriorate and may cause a single mode oscillation to deteriorate. Thus, it is desired that the grating structure be arranged in an entire region in a resonator direction.

There can be a structure in which a grating structure is arranged on an enter resonator and a distribution of a reflectance with respect to the Bragg wavelength is provided in a resonator direction in accordance with the number of stages of a grating layer. However, the effective refractive index has a distribution also in accordance with the number of stages of the grating layer, and hence the effective refractive index is not constant as viewed in the resonator direction. Consequently, a Bragg wavelength determined by the grating structure varies. As a result, a single mode oscillation deteriorates. As a measure for achieving a high single mode oscillation, an optical waveguide structure can be changed. Moreover, a semiconductor laser can have a mesa structure formed in an optical waveguide structure for the purpose of partially concentrating a current injected for drive. There can be a structure in which a width (hereinafter referred to as “mesa width”) in a direction vertical in plan view to a direction of an extension of the mesa structure is adjusted in regions different in grating structure.

Some implementations described herein provide a semiconductor laser excellent in high output characteristic and single mode oscillation.

In some implementations, a semiconductor laser includes: a substrate; an active layer arranged on the substrate; a cladding layer arranged on the active layer, the cladding layer including a first grating layer at least a part of which has a first grating structure, and a second grating layer which is arranged above and apart from at least the part of the first grating layer and at least a part of which has a second grating structure; and an electrode arranged on the cladding layer; wherein the active layer and the cladding layer form a mesa structure, wherein the mesa structure includes a first reflection region and a second reflection region that form a resonator in a direction in which the mesa structure extends, wherein the second grating structure is formed in the first reflection region, wherein any one of the first grating structure or the second grating structure is formed in the second reflection region, wherein the first grating structure and the second grating structure are formed such that a normalized coupling coefficient of the first reflection region is larger than a normalized coupling coefficient of the second reflection region, and wherein the mesa structure in each of the first reflection region and the second reflection region has a mesa width varying in accordance with a refractive index.

### BRIEF DESCRIPTION OF THE DRAWINGS

FIG. 1 is a top view of a semiconductor laser according to a first example implementation of the present invention.

FIG. 2 is a schematic sectional view taken along the line II-II of the semiconductor laser illustrated in FIG. 1.

FIG. 3 is a schematic sectional view taken along the line III-III of the semiconductor laser illustrated in FIG. 1.

FIG. 4 is a schematic sectional view taken along the line IV-IV of the semiconductor laser illustrated in FIG. 1.

FIG. 5 is a top view of a section along the line V-V of the semiconductor laser illustrated in FIG. 3.

FIG. 6 is a top view of a section along the line VI-VI of the semiconductor laser illustrated in FIG. 3.

FIG. 7 is a schematic sectional view of a semiconductor laser according to Modification Example 1 of the first example implementation.

FIG. 8 is a top view of the semiconductor laser according to Modification Example 1 of the first example implementation.

FIG. 9 is a schematic sectional view of a semiconductor laser according to Modification Example 2 of the first example implementation.

FIG. 10 is a top view of the semiconductor laser according to Modification Example 2 of the first example implementation.

FIG. 11 is a top view in which some of layers of a semiconductor laser according to a second example implementation of the present invention may be exposed.

FIG. 12 is a schematic sectional view taken along the line XII-XII of the semiconductor laser illustrated in FIG. 11.

FIG. 13 is a schematic sectional view of a semiconductor laser according to a modification example of the second example implementation.

FIG. 14 is a top view of a semiconductor laser according to a third example implementation of the present invention.

FIG. 15 is a schematic sectional view taken along the line XV-XV of the semiconductor laser illustrated in FIG. 14.

### DETAILED DESCRIPTION

Implementations of the present invention are specifically described in detail in the following with reference to the attached drawings. Throughout the figures for illustrating the implementations, like reference symbols are used to represent members having like functions, and a repeated description thereof is omitted. The drawings referred to in the following are only for illustrating the implementations by way of examples, and are not necessarily drawn to scale. Moreover, some of the implementations may be combined with each other.

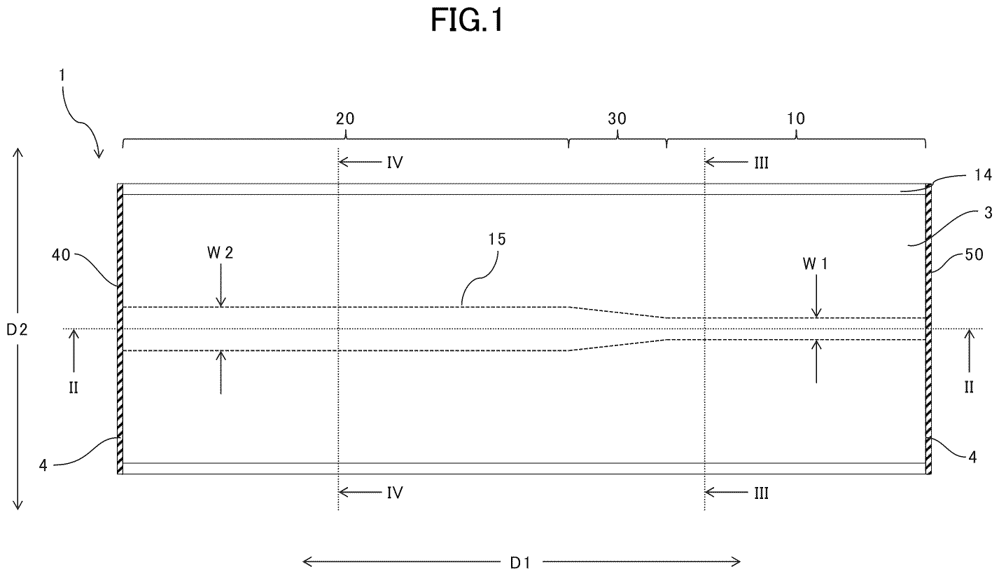

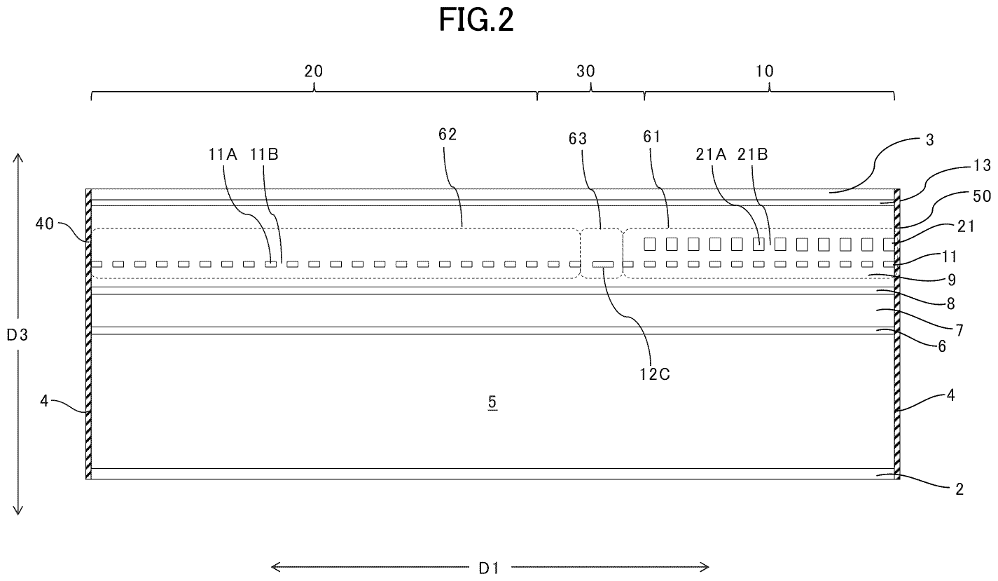

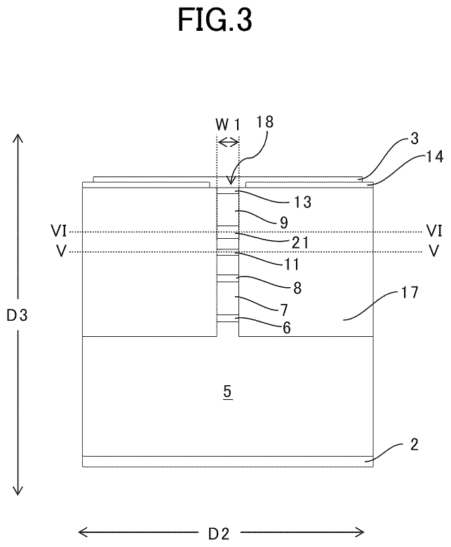

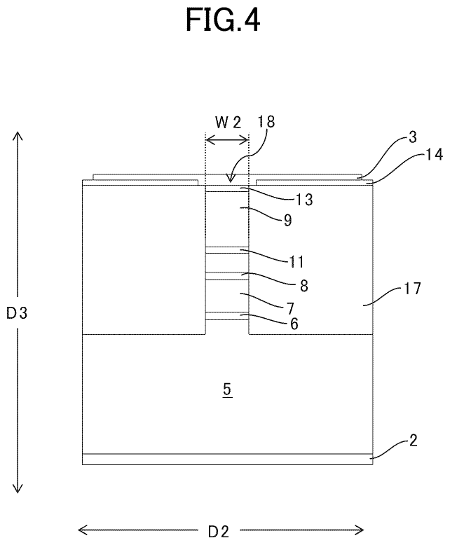

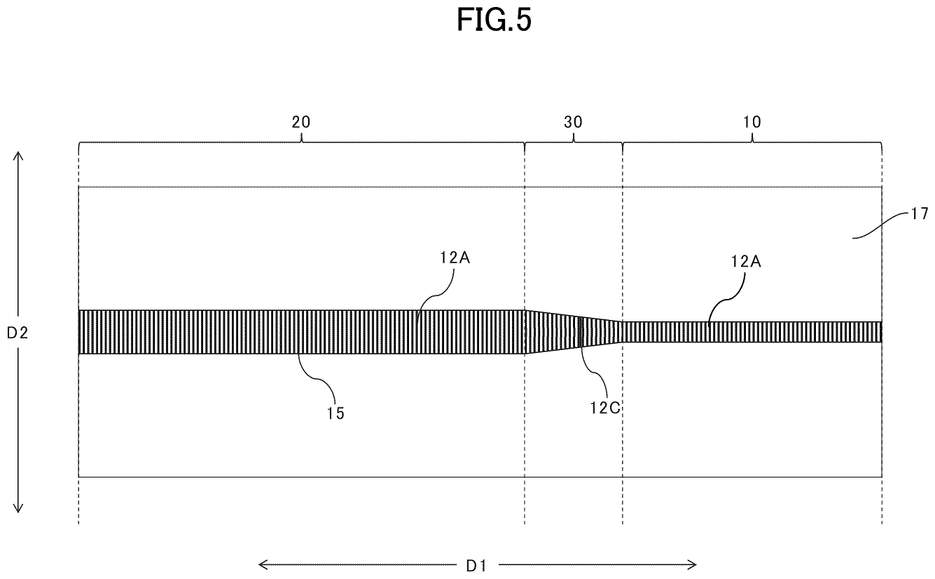

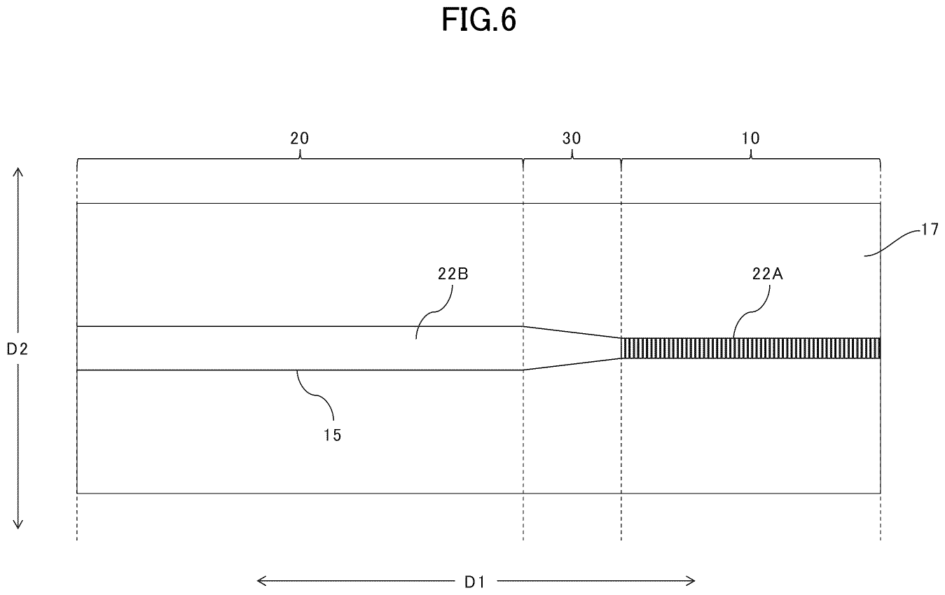

FIG. 1 is a top view of a semiconductor laser 1 according to a first example implementation of the present invention. FIG. 2 shows a schematic sectional view taken along the line II-II of FIG. 1. FIG. 3 shows a schematic sectional view taken along the line III-III of FIG. 1. FIG. 4 shows a schematic sectional view taken along the line IV-IV of FIG. 1. FIG. 5 and FIG. 6 are top views in which some of the layers of the semiconductor laser 1 may be exposed. The semiconductor laser 1 may include a first electrode 2 on a rear surface and a second electrode 3 on a front surface. The first electrode 2 and the second electrode 3 may be metal layers. A light beam may be emitted from a front facet 40 (facet on the left side of FIG. 1) by injecting a current between the first electrode 2 and the second electrode 3. Low reflection films 4 may be formed on the front facet 40 (facet on the left side of FIG. 1) and a rear facet 50 (facet on the right side of FIG. 1). It may be preferred that a reflectance at the facet be 1% or less when the low reflection film 4 is formed.

The semiconductor laser 1 may include semiconductor layers in which an optical confinement layer (SCH layer) 6 of a first conductivity type, an active layer 7, an optical confinement layer 8 (SCH layer) of a second conductivity type, a cladding layer 9 of the second conductivity type, and a contact layer 13 of the second conductivity type are grown in the stated order on a substrate 5 of the first conductivity type. Here, a direction of growth of the semiconductor may be referred to as “third direction D3.” The semiconductor laser 1 may be a DFB laser. The cladding layer 9 of the second conductivity type may include a first grating layer 11 at least a part of which may have first grating structures 12A (described herein) and a second grating layer 21 which may be arranged above and apart from at least a part of the first grating layer 11, and at least a part of which may have a second grating structure 22A (described herein). The active layer 7 may be formed of, for example, a multiple-quantum well layer. Further, the multiple-quantum well layer may be an intrinsic semiconductor or an n-type semiconductor. The first conductivity type may be an n-type and the second conductivity type may be a p-type here, but the first conductivity type may be the p-type and the second conductivity type may be the n-type. Further, those semiconductor layers include a mesa structure 15. The mesa structure 15 extends in a light extraction direction (first direction D1). A lower portion of the mesa structure 15 may be a part of the substrate 5. Both sides of the mesa structure 15 may be covered with a semiconductor buried layer 17 having a semi-insulating property. The buried layer 17 may be a stack formed of semiconductor layers of the p-type and the n-type. The dotted lines of FIG. 1 indicate positions of boundaries between an upper portion of the mesa structure 15 and the buried layer 17.

The semiconductor laser 1 may include an insulating film 14 on the front surface thereof. The insulating film 14 may cover the front surface of the semiconductor laser 1 except for a part of the front surface. The insulating film 14 may include an opening (e.g., a through hole) 18 in a region corresponding to the upper portion of the mesa structure 15. Via the through hole 18, the second electrode 3 and the contact layer 13 of the second conductivity type may be connected to each other, and electric signals may be applied (currents may be injected) to the mesa structure 15. Here, the through hole 18 may have a shape along the first direction D1. Moreover, in a second direction D2 perpendicular to the first direction D1 and the third direction D3, a width of the through hole 18 may be wider than a width of the mesa structure 15. However, both thereof may have the same width. The width of the mesa structure 15 may be a width (hereinafter referred to as “mesa width”) of the formation of the mesa structure in the second direction D2. Mesa widths in the first region 10 and the second region 20 may be referred to as “first mesa width W1” and “second mesa width W2,” respectively. Details of the first region 10 and the second region 20 are described herein.

The first grating layer 11 may include a grating structure of a floating type, and may be formed of regions having the same refractive index as that of the cladding layer 9 of the second conductivity type and regions having a first refractive index different from that of the cladding layer 9 of the second conductivity type in sectional view. Here, when the refractive index of the cladding layer 9 of the second conductivity type is a second refractive index, the first grating layer 11 may include a region in which first refractive index regions 11A and second refractive index regions 11B may be alternately arranged along the first direction D1.

The second grating layer 21 may include a grating structure of the floating type, which may be the same as that of the first grating layer 11, and may be thicker than the first grating layer 11 in the semiconductor stacking direction (third direction D3). The cladding layer 9 may be arranged between the first grating layer 11 and the second grating layer 21. The second grating layer 21 may include a region in which third refractive index regions 21A and fourth refractive index regions 21B formed of the cladding layer 9 may be alternately arranged in the first direction D1 in sectional view. Moreover, in the first example implementation, the first refractive index and the third refractive index may be higher than the second refractive index and the fourth refractive index. However, a relationship among the refractive indices may be inverted. The first refractive index and the third refractive index may be the same as each other or may be different from each other.

The mesa structure 15 may include regions different in mesa width in the first direction D1. That is, the mesa structure of the first reflection region 61 included in the first region 10 may have a mesa width different from that of the mesa structure of the second reflection region 62 included in the second region 20. Specifically, the semiconductor laser 1 may include the first region 10 having the first mesa width W1 and the second region 20 having the mesa width of the second mesa width W2. In the first example implementation, the second mesa width W2 may be wider than the first mesa width W1. Moreover, the mesa structure 15 may include, between the first region 10 and the second region 20, a third region 30 in which the mesa width gradually changes from the first mesa width W1 to the second mesa width W2. It may be desired that the third region 30 be in a tapered shape having a mesa width gradually changing from the first region 10 toward the second region 20. However, boundaries between the third region 30 and the buried layer 17 may change linearly or may change while including a curve in top view. The second electrode 3 may be integrally arranged across the first region 10, the second region 20, and the third region 30. The second electrode 3 may be individually arranged in each region, but in this case, it may be desired that each of the individually arranged electrodes be connected to the same power supply.

FIG. 5 is a top view of the semiconductor laser 1, and is an explanatory view for illustrating a position of each region included in the first grating layer 11. Specifically, as illustrated in FIG. 3, this is a top view of a section (V-V section) in the first grating layer 11. For the convenience of description, a part of the configuration is not shown. The structure (grating structure) which is formed in the first grating layer 11 and in which the first refractive index regions 11A and the second refractive index regions 11B are alternately arranged may be referred to as “first grating structure 12A.” The first grating layer 11 may have the first grating structures 12A on the entire resonator of the semiconductor laser 1 except for a phase shift portion 12C described herein. The first grating structure 12A may be a uniform grating structure in which the first refractive index regions 11A and the second refractive index regions 11B are alternately arranged in the first direction D1 in order to reflect a light beam having a specific Bragg wavelength. The first grating structures 12A in the first example implementation may be arranged at the same period in the first region 10 and the second region 20. However, the first grating structure 12A arranged in the first region 10 and the first grating structure 12A arranged in the second region 20 may be different from each other in phase of light beam to be reflected. The phase is described herein. Here, the first grating structure 12A may be configured to reflect a light beam in a 1.3-μm band. The first grating structure 12A may be configured to reflect a light beam having another Bragg wavelength such as a 1.55-μm band.

FIG. 6 is a top view of the semiconductor laser 1, and is an explanatory view for illustrating a position of each region included in the second grating layer 21. Specifically, as illustrated in FIG. 3, this is a top view of a section (VI-VI section) in the second grating layer 21. For the convenience of description, a part of the configuration is not shown. The structure which is formed in the second grating layer 21 and in which the third refractive index regions 21A and the fourth refractive index regions 21B are alternately arranged may be referred to as “second grating structure 22A.” The second grating structure 22A may be arranged at the same period and at the same position (first direction D1) as those of the first grating structure 12A. That is, each third refractive index region 21A and each first refractive index region 11A may be the same in center position in the first direction D1. Similarly, each fourth refractive index region 21B and each second refractive index region 11B may be the same in center position in the first direction D1. Moreover, a structure in which only the third refractive index regions 21A or the fourth refractive index regions 21B is arranged may be referred to as “second non-grating structure 22B.” In the first example implementation, the second non-grating structure 22B may be formed of only the fourth refractive index region 21B. In other words, the cladding layer 9 may be arranged in a region in which the second grating structure 22A is not formed. The second non-grating structure 22B does not reflect, but transmits the light beam having the Bragg wavelength reflected by the second grating structure 22A.

The first grating layer 11 may include the phase shift portion 12C. The phase shift portion 12C may be a structure in which two of the first refractive index regions 11A are continuously arranged side by side. The phase shift portion 12C may be a structure in which two of the second refractive index regions 11B are continuously arranged side by side. In the first grating structures 12A, the phase of the grating structure shifts by π before and after the phase shift portion 12C. That is, the phase shift portion 12C may be a λ/4 phase shift portion. Here, a shift amount of the phase corresponds to the x shift in consideration of the optical path length. As described herein, effective refractive indices in the first region 10 and the second region 20 may be set to be substantially the same, and hence optical path lengths of the first region 10 and the second region 20 may be substantially the same. Meanwhile, the third region may be the region in which the mesa width changes, and hence may include a region having an effective refractive index different from that in the first region 10 and the second region 20. Thus, the third region may be also different in optical path length from the first region 10 and the second region 20. In the first example implementation, in consideration of the difference in optical path length in the third region 30, a fine adjustment may be made to achieve such a relationship that the phase may be effectively π-shifted between the grating structures in the first region 10 and the grating structures in the second region 20.

Here, a region from the phase shift portion 12C to the rear facet 50 may be referred to as “first reflection region 61.” Moreover, a region from the phase shift portion 12C to the front facet 40 may be referred to as “second reflection region 62.” Moreover, a region between the first reflection region 61 and the second reflection region 62 may be referred to as “phase shift region 63.” Here, the phase shift region 63 may include the phase shift portion 12C. The first reflection region 61 and the second reflection region 62 form a resonator across the phase shift region 63. In other words, a part of the light beam having the Bragg wavelength reflected by the first reflection region 61 may be reflected by the second reflection region 62, and may be returned to the first reflection region 61 side. Similarly, a part of the light beam having the Bragg wavelength reflected by the second reflection region 62 may be reflected by the first reflection region 61, and may be returned to the second reflection region 62 side. Further, in the semiconductor laser 1, the low reflection films 4 may be formed on the front facet 40 and the rear facet 50, and hence a very high single mode oscillation may be achieved. For example, when the single mode oscillation is represented as a yield of a side-mode suppression ratio (SMSR), the single mode oscillation is theoretically 100%. In FIG. 2, the first reflection region 61, the second reflection region 62, and the phase shift region 63 indicate the regions in which the first grating layer 11 and the second grating layer 21 may be arranged. However, this may be simplification for the convenience of the description, and an entire region also including the upper and lower semiconductor layers of the grating layer actually forms each region.

The first reflection region 61 may include the first grating structure 12A of the first grating layer 11 and the second grating structure 22A of the second grating layer 21. In other words, in the first reflection region 61, the grating structures may be formed at the two stages. The first reflection region 61 may be arranged across the first region 10 and a part of the third region 30. Here, the first reflection region 61 in the third region 30 may include only the first grating structure 12A, and hence the grating structure may be at one stage. In other words, an end portion of the second grating structure 22A substantially matches an interface between the first region 10 and the third region 30. However, the configuration is not limited to this example, and, for example, the second grating structure 22A may be arranged in the third region 30. When the second grating structure 22A extended and is arranged above also the phase shift portion 12C, a phase shift portion may be arranged in also the second grating layer 21. Additionally, or alternatively, the end portion of the second grating structure 22A may be arranged on the rear facet 50 side with respect to the interface between the first region 10 and the third region 30. However, it may be desired that the second grating structure 22A be arranged in a range of 80% or more of the first region 10.

The second reflection region 62 may include the first grating structure 12A of the first grating layer 11 and the second non-grating structure 22B of the second grating layer 21. In other words, the grating structure included in the second reflection region 62 may be only one stage of the first grating structure 12A. The second reflection region 62 may be arranged across the second region 20 and a part of the third region 30. Here, the first grating structure 12A of the second reflection region 62 may be arranged on an entire surface of the second region 20 in the first direction D1, but the configuration is not limited to this example. It may be desired that the first grating structure 12A be arranged in a region of at least 80% or more of the second region 20.

In some implementations, coupling coefficients of the first reflection region 61 and the second reflection region 62 may be represented by κ1 and κ2, respectively. The coupling coefficients κ may be determined by a structure of the semiconductor multilayer, the grating structure, and the like. In the first example implementation, the semiconductor multilayers included in the first reflection region 61 and the second reflection region 62 may be substantially the same. Thus, a difference between κ1 and κ2 may be mainly caused by a difference in the grating structure. The first reflection region 61 may include two stages of the grating structure while the second reflection region 62 may include one stage of the grating structure, and hence κ1 and κ2 may be different from each other. The number of stages of the grating structure in the first reflection region 61 may be larger than that in the second reflection region 62, and hence κ1 may be larger than κ2.

Moreover, the lengths in the first direction D1 of the first reflection region 61 and the second reflection region 62 may be represented by L1 and L2, respectively. As described above, L1 is not a length of the first region 10 having the mesa width of W1. L2 is not a length of the second region 20 having the mesa width of W2. Each of L1 and L2 indicates a length of the region in which the grating structures may be arranged as viewed from the phase shift portion 12C. L2 may be longer than L1.

In the first example implementation, a normalized coupling coefficient κ1L1 of the first reflection region 61 may be larger than a normalized coupling coefficient κ2L2 of the second reflection region 62. This may be achieved by adjusting a thickness and a composition of each of the grating structures such that κl is larger than κ2. A light output intensity of a facet having a smaller normalized coupling coefficient on one side of the phase shift portion 12C may be higher. In other words, in the semiconductor laser 1, a light output intensity output from the front facet 40 may be higher than a light output intensity from the rear facet 50. When the normalized coupling coefficients of the first reflection region 61 and the second reflection region 62 are the same, the light intensities output from both facets are the same. The “front” and the “rear” as used here are merely naming used for the sake of convenience, and a facet having higher light output may be just referred to as a “front facet.” In a general optical communication, a higher light intensity may be preferred, and a light beam from the front facet may be used for the optical communication. As described above, the light output intensity from the facet on one side may be increased by arranging the regions having the normalized coupling coefficients different from each other in accordance with the number of stages of the grating structure. Further, the grating structures (here, the first grating structures 12A) may be arranged over the entire resonator, and hence, for example, scattering of the light beam may be suppressed, which contributes to achievement of high output.

The coupling coefficient κ1 of the first reflection region 61 may be determined by both of structures of the first region 10 and the third region 30. In the first example implementation, the second grating structure 22A may be arranged only in the first region 10. When the second grating structure 22A is arranged also in the third region 30, the coupling coefficient κ1 may be larger. Similarly, the second reflection region 62 may include only the first grating structure 12A. However, when the second grating structure 22A is included in a part of the third region 30, the coupling coefficient κ2 may be larger. Even when those configurations are employed, when κ1L1 of the first reflection region 61 is larger than κ2L2 of the second reflection region 62, the light output intensity from the front facet 40 may be increased.

It may be preferred that κL1 be 60% or more (that is, κ2L2 be 40% or less) with respect to a normalized coupling coefficient of the entire semiconductor laser 1. Further, when L1 is increased to increase κ1L1, a ratio of the second region 20, which increases the light output, to the entire element may be decreased. A main region of the second reflection region 62 may be the second region 20, and may have a wider mesa width than that of the first region 10, which may be a main region of the first reflection region 61. That is, the mesa structure in each of the first reflection region 61 and the second reflection region 62 may have a mesa width varying in accordance with the refractive index. A mesa structure having a wider mesa width may generate a larger total amount of light beams, and a mesa structure having a longer second region 20 may be more excellent in high output characteristic. In this case, an effect of the increase in output is not sufficiently obtained, and hence it may be preferred that κ1L1 be 70% or more. When a higher output characteristic is required, it may be preferred that κ1L1 be 80% or more.

A resonator length of the semiconductor laser 1 may be a total length of the entire first region 10, second region 20, and third region 30 in the first direction D1. In a stricter sense, the low reflection films 4 may be formed on both of the facets of the semiconductor laser 1, and hence the resonator length may be a length along which the grating structures are arranged. Here, the resonator length may be a length along which the first grating structures 12A are arranged. In order to increase the light output intensity from the front facet 40, it may be preferred that the first reflection region 61 exist on the rear side. Moreover, it may be preferred that the first reflection region 61 be arranged so that the first reflection region 61 40% or less of the resonator length. That is, it may be preferred that the length of the first reflection region 61 in the first direction D1 be 40% or less of the length of the entire grating layer (regions in which the first grating structures 12A are arranged). It may be more preferred that the length be 30% or less thereof. However, when κ1L1 is smaller than 1, a threshold value for oscillation increases, which may not be preferred in terms of consumed electric power. Thus, it may be required to set κ1L1 such that κ1L1 is 1 or more, more preferably 1.5 or more.

In order to obtain a high single mode oscillation, it may be required that the Bragg wavelengths of the light beams reflected in the first reflection region 61 and the second reflection region 62 be the same. The Bragg wavelength may be proportional to the effective refractive index of the region through which the light beam propagates and the period of the grating structure. The effective refractive index depends on a semiconductor structure and the mesa width of the region through which the light beam propagates. The first reflection region 61 and the second reflection region 62 may be different in the number of stages of the included grating structure, and hence the first reflection region 61 and the second reflection region 62 may be different in configuration of the semiconductor layers. Thus, when the mesa widths of the regions in which the first reflection region 61 and the second reflection region 62 are included are the same, the effective refractive indices thereof may be different from each other. Thus, in order to make the first reflection region 61 and the second reflection region 62 have the same Bragg wavelength, it may be required to differentiate the periods of the grating structures thereof from each other. However, it may not be preferred in the viewpoint of manufacturing to form regions different in period of the grating structure in one semiconductor element. For example, the period of the grating structure corresponding to the 1.3-μm band may be approximately 200 nm, and hence very fine machining may be required. Moreover, a difference in effective refractive index in accordance with the number of stages of the grating structure may be small, and when this difference is adjusted through the grating period, a difference in period may be very small. For example, the difference in period may be 1 nm or shorter. Thus, it may not be preferred in the viewpoint of process accuracy to form regions very slightly different in grating period in one semiconductor element. If a desired period of the grating structure cannot be obtained due to a variation in process, oscillation at a single wavelength cannot be obtained, which may not be preferred as the semiconductor laser. It may thus be preferred that the first reflection region 61 and the second reflection region 62 be formed so that the grating periods thereof are the same.

In the first example implementation, the mesa width is changed to match the effective refractive indices with each other. The effective refractive index of the first region 10 which occupies the main region of the first reflection region 61 may be higher than the effective refractive index of the second region 20 which occupies the main region of the second reflection region 62. This is mainly because the third refractive index regions 21A are included in the first region 10. Thus, the mesa width W2 of the second region 20 may be set to be wider than the mesa width W1 of the first region 10, to thereby make the effective refractive indices of the first region 10 and the second region 20 substantially the same. Here, the state in which the effective refractive indices are the same means a state in which a difference between the effective refractive index of the first reflection region 61 and the effective refractive index of the second reflection region 62 is 0.5% or less. For example, W1 may be 2 μm, and W2 may be 2.2 μm. Compared with the period of the grating, the difference in mesa width may be sufficiently large in scale, and hence the first region 10 and the second region 20 can stably be manufactured. With this structure, the first reflection region 61 and the second reflection region 62 may be the same in period of the grating structure, and hence the reflection at the same Bragg wavelength occurs. Thus, the oscillation at a single wavelength may be obtained. Here, the state in which the periods of the grating structures are the same means a state in which the grating structures are formed in the same manufacturing process, and when the periods are within a manufacturing variation (for example, a variation in an etching process at the time of the manufacturing of the grating), the periods are considered to be the same.

It may be desired that the mesa width W1 of the first region 10 be set to be equal to or narrower than a width at which a transverse high-order mode does not occur for the light beam having the Bragg wavelength. In other words, it may be desired that W1 be set to be equal to or narrower than a cutoff width. For example, the wavelength of the light beam may be in the 1.3-μm band, it may be desired that W1 be 2 μm or less. Moreover, an occurrence condition for the transverse high-order mode may change in accordance with a drive condition. In order to obtain a stable suppression effect for the transverse high-order mode, it may be preferred that W1 be 1.5 times or less the Bragg wavelength. For example, when the Bragg wavelength is 1.3 μm, it may be preferred that W1 be 1.95 μm or less. The second mesa width W2 of the second region 20 may be set to be wider than the first mesa width W1 in order to match the effective refractive indices of each other in the first example implementation as described above. It may be also desired that the mesa width W2 of the second region be equal to or shorter than the cutoff width in order to suppress the occurrence of the transverse high-order mode, but the configuration is not limited to this example. For example, when the first mesa width W1 is in a vicinity of the cutoff width, the second mesa width at which the effective refractive indices match each other may be wider than the cutoff width, but this state may be allowed. As the mesa width may be wider, the total amount of generated light beams increases, and hence the light output intensity of the semiconductor laser 1 can be increased. When the second mesa width W2 is equal to or longer than the cutoff width, even when the transverse high-order mode occurs, the light beams in the transverse high-order mode may not be reflected in the first region 10, and hence light beams having a high intensity in the transverse high-order mode may not be output from the front facet 40.

Here, the third region 30 in which the mesa width changes causes a decrease in single mode oscillation. In particular, the region which does not include the second grating structure 22A may be lower in effective refractive index than the first region 10. Moreover, the mesa width may be also shorter than W2, and hence the effect of increasing the effective refractive index obtained by increasing the mesa width may also be limited. Thus, it may be preferred in the viewpoint of the single mode oscillation that a ratio of the third region 30 to the entire resonator of the semiconductor laser 1 be small. In the first reflection region 61 which is arranged across both of the first region 10 and the third region 30, when the ratio of the arrangement of the third region 30 is 20% or less, influence on deterioration of the single mode oscillation may be low. Similarly, in the second reflection region 62 which may be arranged across both of the second region 20 and the third region 30, it may be preferred that the ratio of the arrangement of the third region 30 be 20% or less.

Moreover, it may be desired that the phase shift portion 12C be arranged in the third region 30. Even when the phase shift portion 12C is arranged in the first region 10 or the second region 20, when a relationship of κ1L1>κ2L2 is satisfied, a high output characteristic may be obtained. There may be a structure in which the phase shift portion 12C is arranged in the first region 10 and the second grating structure 22A is not included between the phase shift portion 12C and the front facet 40. That is, the second grating structure 22A may be arranged only in the first reflection region 61. The second reflection region 62 may be arranged across a part of the first region 10, the entire third region 30, and the entire second region 20. The second reflection region 62 in the first region 10 may have a structure in which the mesa width is W1 and the number of stages of the grating structure is one. As described above, the mesa width W1 may be set such that the light beam having a desired Bragg wavelength is reflected when the number of stages of the grating structure is two. Thus, a wavelength of the light beam reflected in the region of the second reflection region 62 included in the first region 10 may be deviated from the Bragg wavelength. Moreover, as described above, a wavelength of a light beam reflected in the region of the second reflection region 62 included in the third region 30 may be deviated from the Bragg wavelength due to the mesa width narrower than W2. Thus, in the case in which the phase shift portion 12C is arranged in the first region 10, compared with the case in which the phase shift portion 12C is arranged in the third region 30, the region in which the Bragg wavelength may be deviated extends. As a result, a single mode oscillation decreases. This causes a decrease in side-mode suppression ratio characteristic, for example. The same applies to a case in which the phase shift portion 12C is included in the second region 20, and the first reflection region 61 is arranged across a part of the second region 20, the entire third region 30, and the entire first region 10. The number of stages of the grating structure may be two in a part of the second region 20, and the effective refractive index may be large. Thus, the Bragg wavelength may be deviated toward a higher side. As a result, the single mode oscillation decreases. As described above, when the phase shift portion 12C is arranged in the first region 10 or the second region 20, the region in which the Bragg wavelength is deviated increases, which may not be preferred in the viewpoint of the single mode oscillation. In the first example implementation, by arranging the phase shift portion 12C in the third region 30, the region in which the Bragg wavelength is deviated may be minimized, and hence the deterioration of the single mode oscillation may be suppressed. When, for example, an end portion of the second grating structure 22A and end portions of the first region 10 and the third region 30 completely match each other, even when the phase shift portion 12C is arranged in the first region, the region having the different Bragg wavelength does not extend. However, it may be difficult to completely match the end portion of the grating structure and the end portion of the region in which the mesa width changes with each other in consideration of manufacturing variation, and hence it may be preferred in the viewpoint of yield that the phase shift portion 12C be intentionally arranged in the third region 30.

The second electrode 3 may be arranged across the first region 10, the second region 20, and the third region 30, and may be substantially the same in level of change in the effective refractive index in accordance with the injected current amount. Thus, the high single mode oscillation may be achieved under a wide operating condition.

As described above, the semiconductor laser 1 according to the first example implementation may include the phase shift portion 12C, and the first grating structures 12A may be arranged across the entire resonator. Moreover, the grating structures may be discretely arranged. As a result, the scattering of the light beam may be avoided, and the high output characteristic may be achieved.

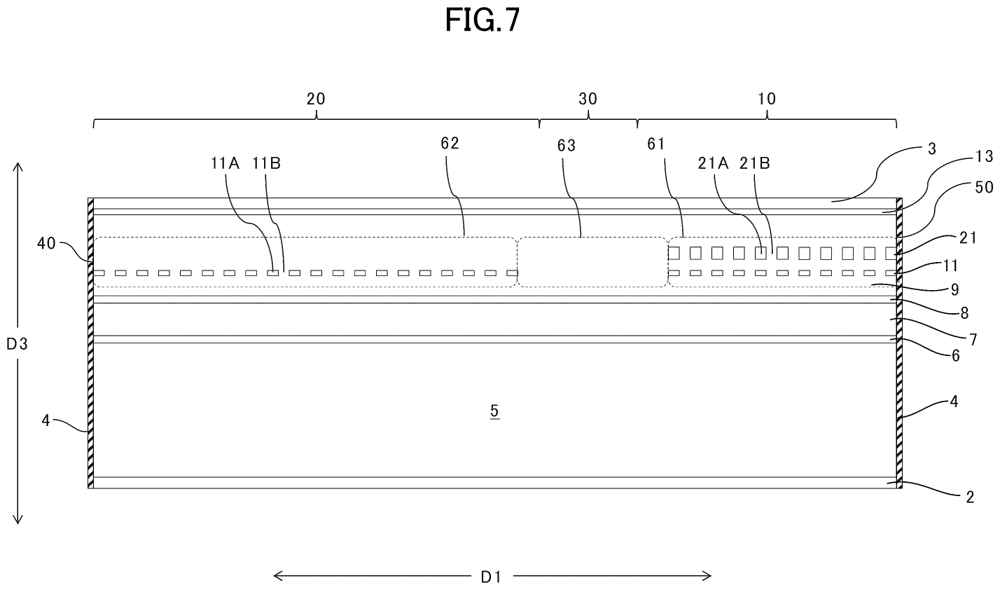

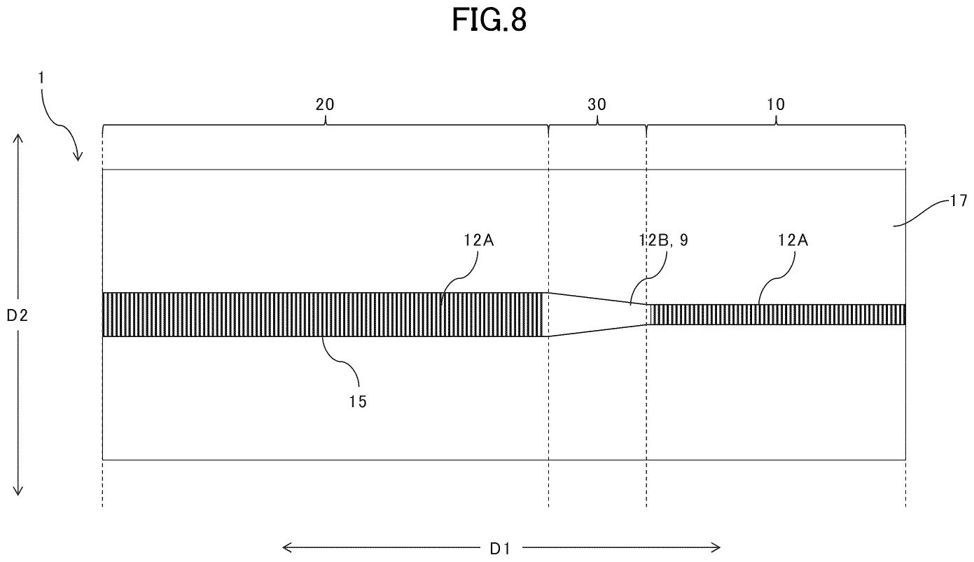

FIG. 7 is a sectional view of the semiconductor laser 1 according to Modification Example 1 of the first example implementation, and is a view corresponding to FIG. 2. FIG. 8 is a top view of the semiconductor laser 1 according to Modification Example 1 of the first example implementation, and is a view corresponding to FIG. 5. A main difference from the first example implementation is a structure of the phase shift region 63.

In Modification Example 1, the first grating structures 12A of the first grating layer 11 are not continuously arranged in the first direction D1, and are not arranged in a part of the first region 10, the whole of the third region 30, and a part of the second region 20. In those regions, a first non-grating structure 12B may be arranged. In the first non-grating structure 12B, only any one of the first refractive index region 11A or the second refractive index region 11B may be arranged. The first non-grating structure 12B does not reflect, but transmits the light beam having the Bragg wavelength reflected by the first grating structures 12A. Here, in the first non-grating structure 12B, only the second refractive index region 11B is arranged. In other words, the first grating layer 11 may have a structure in which two first grating structures 12A and the cladding layer 9 therebetween may be arranged.

In Modification Example 1, the phase shift region 63 may be a region in which none of the first grating structure 12A and the second grating structure 22A is arranged. In other words, the phase shift region 63 may be a region in which the first non-grating structure 12B and the second non-grating structure 22B may be arranged. The first reflection region 61 may be a region which exists between the phase shift region 63 and the rear facet 50, and in which at least the second grating structure 22A is arranged. In Modification Example 1, the first reflection region 61 may also include the first grating structure 12A. Thus, the first reflection region 61 may include two stages of the grating structure. The second reflection region 62 may be a region which exists between the phase shift region 63 and the front facet 40, and in which the first grating structure 12A is arranged. As in the first example implementation, the first grating structures 12A arranged in the first reflection region 61 and the second reflection region 62 may have the same period, and the phase may be x-shifted therebetween. Here, the x-shift of the phase between the grating structures may be the phase shift in consideration of the optical path lengths as described above.

In Modification Example 1, none of the first grating structure 12A and the second grating structure 22A is arranged in the third region 30 in which the mesa width changes. Thus, reflection of a light beam having a wavelength different from that of the light beam having a desired Bragg wavelength, which is described in the first example implementation, does not occur. That is, a more excellent semiconductor optical element may be achieved in the viewpoint of the single mode oscillation. However, when a length of the first non-grating structure 12B in the first direction D1 is longer than a half of a length of the first grating structure 12A arranged in the first region 10, oscillation at a wavelength different from a desired Bragg wavelength possibly occurs. Thus, it may be preferred that the length of the first non-grating structure 12B be equal to or shorter than the half of the length of the first grating structure 12A arranged in the first region.

Also in Modification Example 1, the normalized coupling coefficient κ1L1 of the first reflection region 61 may be larger than the normalized coupling coefficient κ2L2 of the second reflection region 62. Thus, the light output intensity output from the front facet 40 may be higher than the light output intensity output from the rear facet 50.

In Modification Example 1, the grating structures do not completely continue, and discontinue at the phase shift region 63. Thus, compared with the first example implementation, the scattering of the light beam possibly occurs. However, the number of regions in which the grating structure discontinues may be smaller (only one). Thus, even when the scattering of the light beam occurs, influence thereof may be small. Thus, a semiconductor laser excellent in the single mode oscillation and also excellent in high output characteristic is achieved.

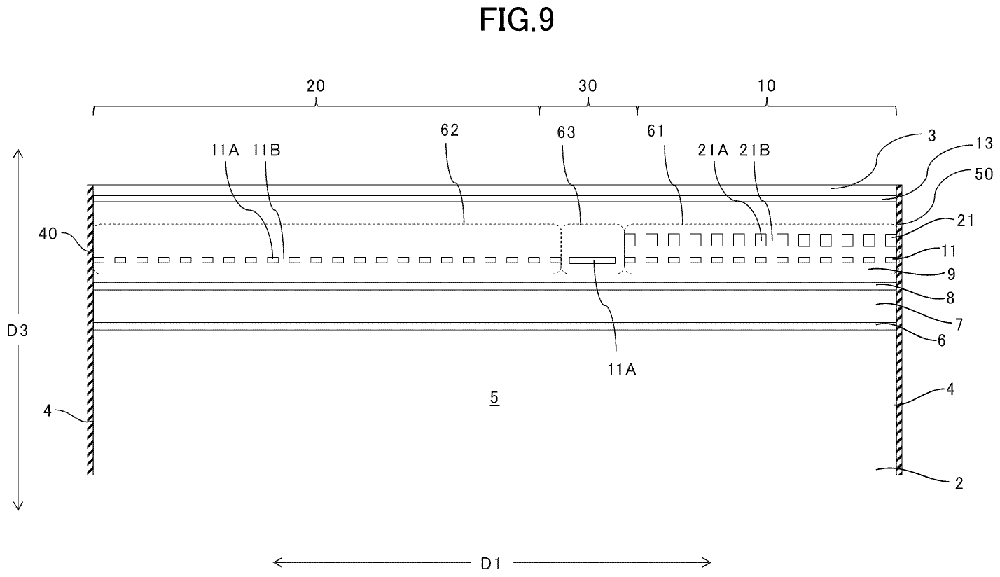

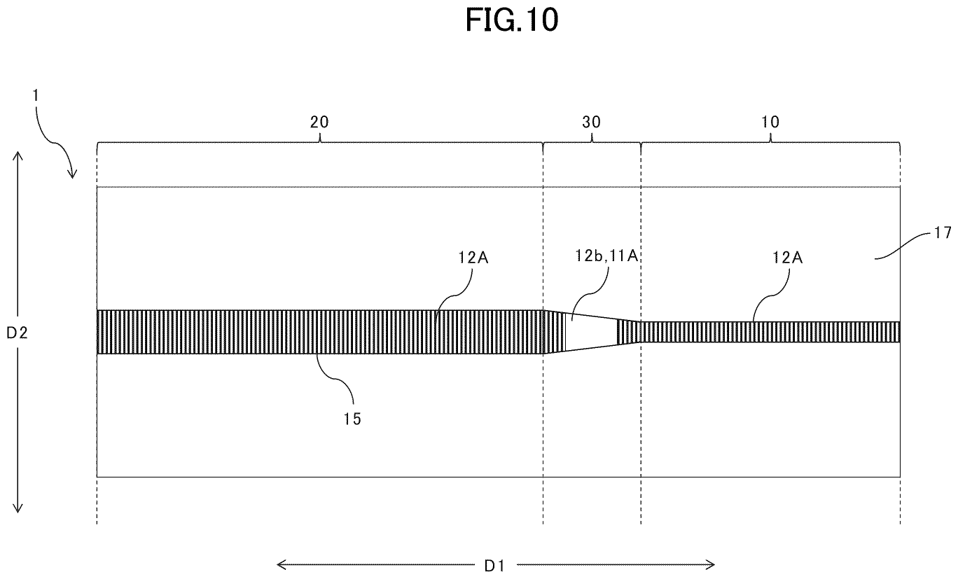

FIG. 9 is a sectional view of the semiconductor laser 1 according to Modification Example 2 of the first example implementation, and is a view corresponding to FIG. 2. FIG. 10 is a top view of the semiconductor laser 1 according to Modification Example 2 of the first example implementation, and is a view corresponding to FIG. 5. A main difference from the first example implementation is a structure of the phase shift region 63.

In Modification Example 2, the first grating structures 12A of the first grating layer 11 are not arranged in the third region 30, and hence do not continue in the first direction D1. In the region in which the first grating structure 12A of the first grating layer 11 is not arranged, the first non-grating structure 12B may be arranged. Here, the first non-grating structure 12B may be the first refractive index region 11A. The remaining structure may be the same as that in Modification Example 1 of the first example implementation.

As described above, the region which is out of the first reflection region 61 and is arranged in the third region 30 reflects a light beam having a wavelength different from a desired Bragg wavelength. However, as in the first example implementation, when the ratio of the third region 30 to the first reflection region 61 is 20% or less, the influence thereof is allowed. The same applies to the second reflection region 62.

The Modification Example 1 and Modification Example 2 may be combined with each other. Specifically, for example, the first reflection region 61 may have the structure in Modification Example 1, and the second reflection region 62 may have the structure in Modification Example 2. In other words, the first region 10 may include the first reflection region 61 and a part of the phase shift region 63, and the second region 20 may include the second reflection region 62. Moreover, the third region 30 may have a configuration in which the third region 30 includes a part of the second reflection region 62 and a part of the phase shift region 63.

As described above, the phase shift region 63 may include the phase shift portion 12C as described in the first example implementation, or may have a configuration in which no grating structure is included. When the phase shift region 63 does not include the grating structure, the phase shift region 63 may be arranged in a part of the first region 10 or the second region 20.

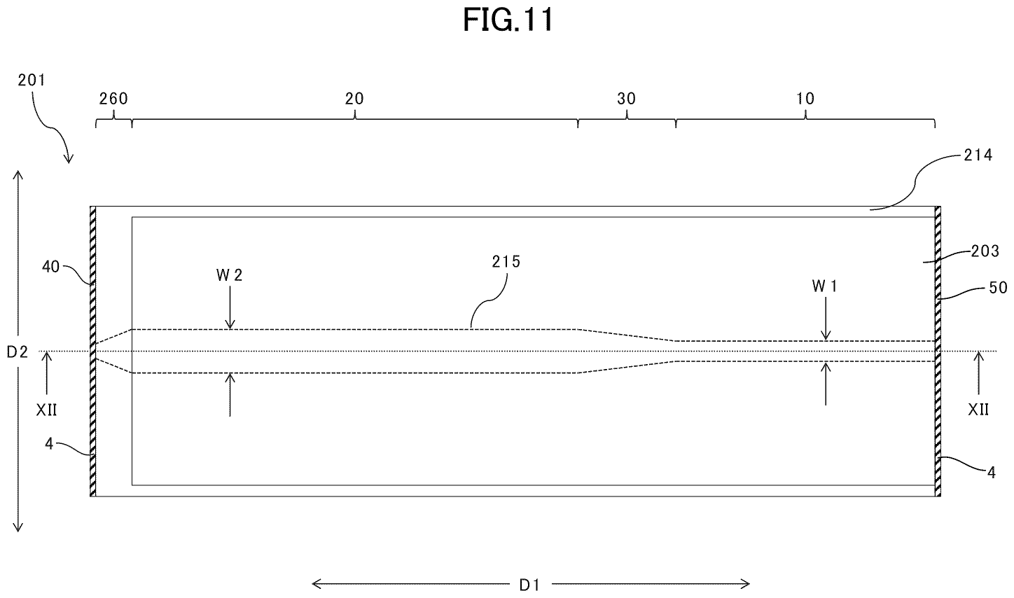

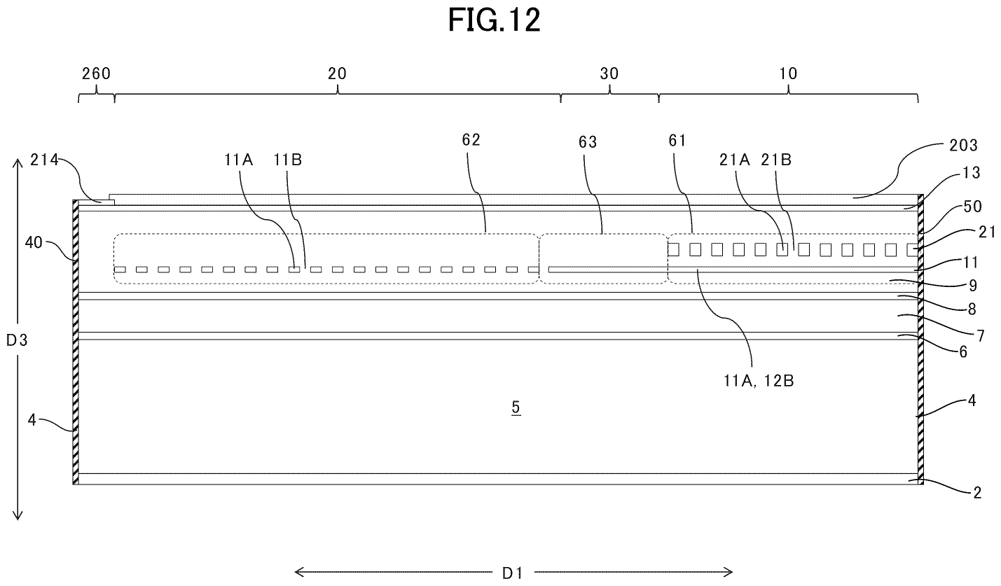

FIG. 11 is a top view of a semiconductor laser 201 according to a second example implementation of the present invention, and corresponds to FIG. 1. FIG. 12 shows a schematic sectional view taken along the line XII-XII of FIG. 11, and corresponds to FIG. 2. The second example implementation is different from the first example implementation in that the semiconductor laser 201 may include a spot size conversion region 260 between the second region 20 and the front facet 40 and in the structures of the first reflection region 61 and the phase shift region 63.

In the second example implementation, in the first grating layer 11, the first non-grating structure 12B may be arranged from the rear facet 50 side toward the front facet 40 side to a middle of the second region 20, and the first grating structure 12A may be arranged from the middle of the second region 20. Moreover, the first non-grating structure 12B may be formed of the first refractive index region 11A. The second grating layer 21 may be the same as that in the first example implementation.

As in the first example implementation, the mesa width of the semiconductor laser 201 may be different between the first region 10 and the second region 20. That is, the mesa structure of the first reflection region 61 included in the first region 10 may have a mesa width different from that of the mesa structure of the second reflection region 62 included in the second region 20. Specifically, a mesa structure 215 may have the first mesa width W1 in the first region 10 and the second mesa width W2 in the second region 20. The second mesa width W2 may be wider than the first mesa width W1. That is, the mesa structure in the first reflection region 61 may be narrower in mesa width than the mesa structure in the second reflection region 62. Moreover, the mesa width in the third region 30 changes from the first mesa width W1 to the second mesa width W2. The spot size conversion region 260 may also be a part of the mesa structure 215. Further, in the spot size conversion region 260, the mesa width gradually decreases from the second mesa width W2 toward the front facet 40, and the narrowest position may be a position in contact with the front facet 40. The mesa width of the spot size conversion region 260 in a portion closest to the front facet 40 may be set so that a desired light output shape is obtained. This mesa width is, for example, narrower than the first mesa width W1.

The spot size conversion region 260 may have the same semiconductor multilayer structure as that of the first region 10 and the second region 20 except for the grating structure. In the spot size conversion region 260, the first grating layer 11 may be the first non-grating structure 12B, and the second grating layer 21 may be the second non-grating structure 22B. In the spot size conversion region 260, both of the two non-grating structures may be the cladding layer 9 (the second refractive index region 11B and the fourth refractive index region 21B). In the second example implementation, the contact layer 13 of the second conductivity type and the insulating film 214 may be arranged on the cladding layer 9 of the second conductivity type, but it is not required that the contact layer 13 be included between the cladding layer 9 and the insulating film 214. Moreover, in a vicinity of a connection portion of the spot size conversion region 260 on the second region 20 side, the first grating structure 12A may be included. Further, a part of the second electrode 3 extends to the spot size conversion region 260, but the configuration is not limited to this example. The second electrode 3 may be arranged in the entire spot size conversion region 260.

In the second example implementation, the first reflection region 61 may be a region in which the first non-grating structure 12B formed of the first refractive index region 11A and the second grating structure 22A may be arranged. The second reflection region 62 may be a region in which the first grating structure 12A and the second non-grating structure 22B formed of the fourth refractive index region 21B are arranged. Moreover, the phase shift region 63 may be a region between the first reflection region 61 and the second reflection region 62. A main region of the phase shift region 63 may be the first non-grating structure 12B formed of the first refractive index region 11A. Thus, the light beam reflected in the first reflection region 61 may be transmitted and propagates to the second reflection region 62. In the phase shift region 63, the first non-grating structure 12B may be the second refractive index region 11B (cladding layer 9).

As in the first example implementation, the period of the second grating structure 22A in the first reflection region 61 and the period of the first grating structure 12A in the second reflection region 62 may be the same. Moreover, the phases may be x-shifted from each other in consideration of optical path lengths of the mutual grating structures. Further, κ1L1 of the first reflection region 61 may be larger than κ2L2 of the second reflection region 62.

In particular, influence of diffraction spread of the first grating layer 11 may be suppressed, and hence manufacturability of the grating structure may be increased.

In the second example implementation, in each of the first reflection region 61 and the second reflection region 62, only one stage of the grating structure is included. However, a thickness of the second grating structure 22A included in the first reflection region 61 in the third direction D3 may be larger than a thickness of the first grating structure 12A included in the second reflection region 62. Thus, the coupling coefficient κ1 of the first reflection region 61 may be larger than the coupling coefficient κ2 of the second reflection region 62. As described above, it may not be always required for the first reflection region 61 to include two stages of the grating structure, and the difference in coupling coefficient may be achieved by the thickness of the grating layer. Moreover, the coupling coefficients may be adjusted by differentiating a composition between two grating layers. Also in the second example implementation, the difference between the normalized coupling coefficient of the first reflection region 61 and the normalized coupling coefficient of the second reflection region 62 can sufficiently be secured while the single mode oscillation may be maintained, and hence the light output intensity from the front facet 40 may be increased. Moreover, by adjusting the first mesa width W1 and the second mesa width W2 to make the effective refractive indices the same, the single mode oscillation may be increased while the grating period is maintained.

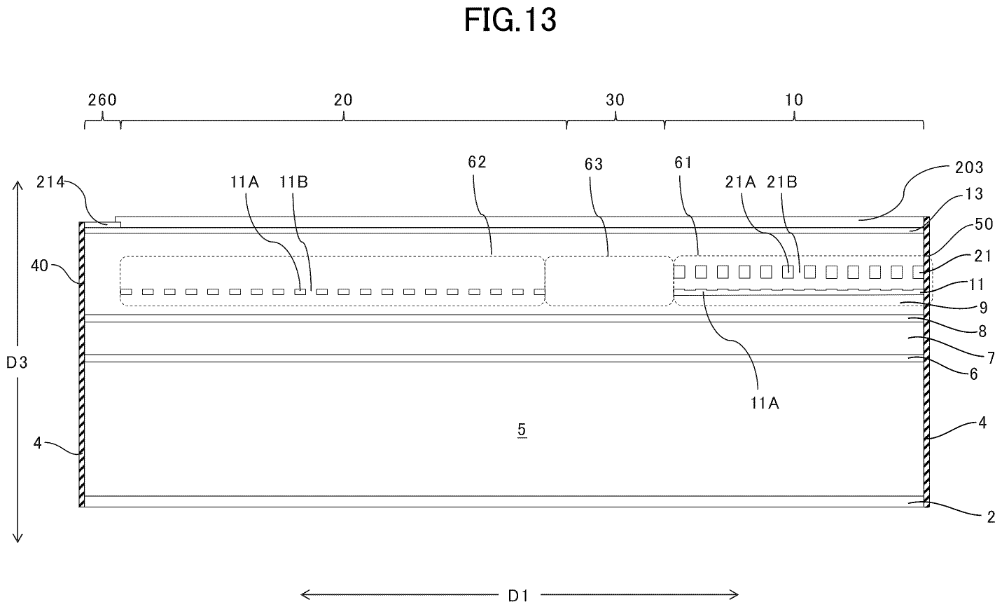

FIG. 13 is a sectional view of the semiconductor laser 201 according to a modification example of the second example implementation, and is a view corresponding to FIG. 2. A difference between this modification example and the second example implementation resides in a configuration of the first grating layer 11. In this modification example, the first non-grating structure 12B is arranged in the phase shift region 63 as in the second example implementation, but is here the second refractive index region 11B (cladding layer 9). Moreover, in the first reflection region 61, an uneven structure is formed in a vicinity of the surface layer of the first refractive index region 11A. This is an example in which the uneven structure is simultaneously formed with the second grating structure 22A of the second grating layer 21. The second grating structure 22A may be formed through etching under a state in which a region which is to remain as the third refractive index region 21A may be masked and a region which is to form the fourth refractive index region 21B may not be masked. It may be preferred that only the second grating layer 21 be etched, but the etching progresses and thus the vicinity of the surface layer of the first grating layer 11 may also be sometimes etched. In this case, as in this modification example, the uneven structure may be formed in the vicinity of the surface layer of the first refractive index region 11A. The uneven structure may be also small compared with the first grating structure 12A, but may contribute to the reflection of the light beam. That is, the uneven structure influences the coupling coefficient κ1. Meanwhile, the period of the uneven structure may be the same as that of the second grating structure 22A, and hence the uneven structure does not influence the single mode oscillation. Also in this modification example, by setting κ1L1 of the first reflection region 61 to be larger than κ2L2 of the second reflection region 62, the high output characteristic and the high single mode oscillation may be simultaneously achieved.

Moreover, in the phase shift region 63, the first grating structure 12A may be arranged as in the first example implementation, and the phase shift portion 12C may be arranged in the middle thereof.

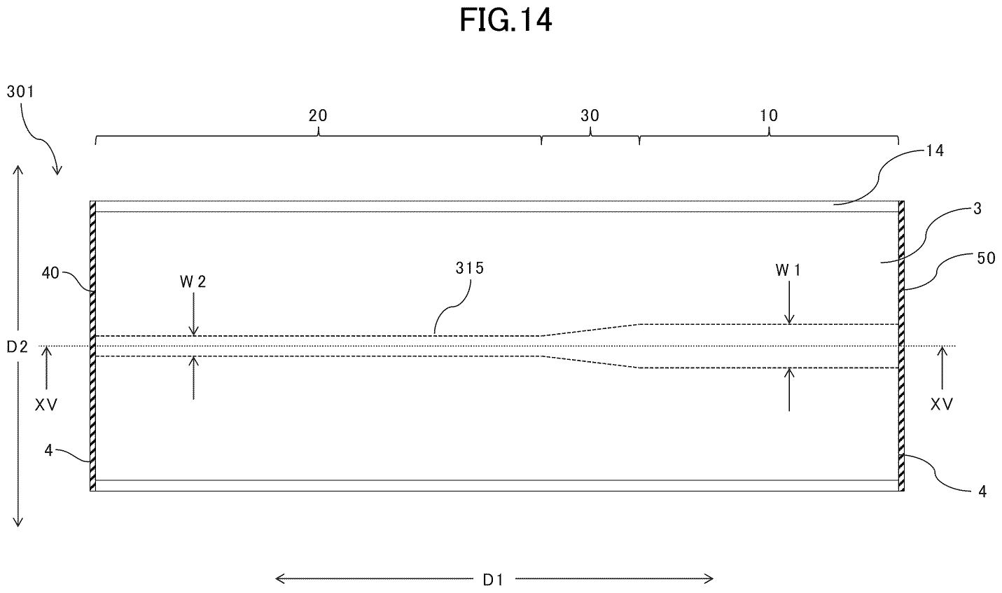

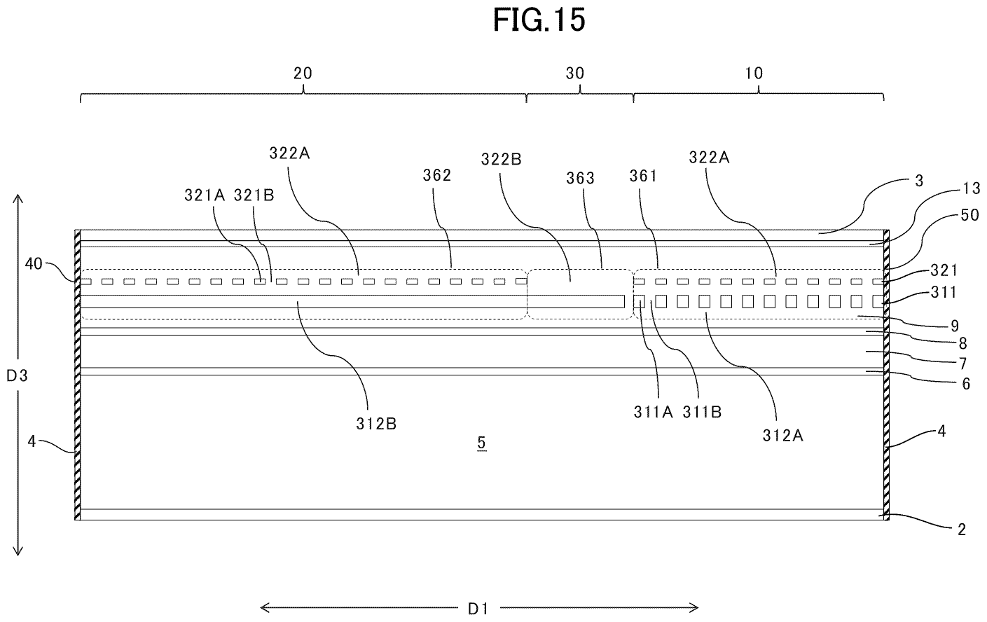

FIG. 14 is a top view of a semiconductor laser 301 according to a third example implementation of the present invention, and corresponds to FIG. 1. FIG. 15 is a schematic sectional view taken along the line XV-XV of FIG. 14, and corresponds to FIG. 2. A main difference between the third example implementation and the first example implementation resides in the grating structures included in the first reflection region 61, the second reflection region 62, and the phase shift region 63 and the mesa widths of the first region 10 and the second region 20.

In the third example implementation, a first grating layer 311 may include first refractive index regions 311A and second refractive index regions 311B. A second grating layer 321 may include third refractive index regions 321A and fourth refractive index regions 321B. Here, the second refractive index region 311B and the fourth refractive index region 321B may be the cladding layer 9. Moreover, the refractive indices of the first refractive index region 311A and the third refractive index region 321A may be higher than the refractive indices of the second refractive index region 311B and the fourth refractive index region 321B. However, this relationship may be inverted. The refractive indices of the first refractive index region 311A and the third refractive index region 321A may be the same as each other, or may be different from each other. Moreover, the first grating layer 311 may be thicker than the second grating layer 321 in the third direction D3.

The first grating layer 311 may include a first grating structure 312A in which the first refractive index regions 311A and the second refractive index regions 311B are alternately arranged. The first grating layer 311 may include a first non-grating structure 312B which transmits a light beam reflected by the first grating structure 312A. Here, the first non-grating structure 312B may be formed of the first refractive index region 311A, but may be formed of the second refractive index region 311B. The first grating structure 312A may be arranged in the first region 10. The first non-grating structure 312B may be arranged in the second region 20 and the third region 30. The first region 10, the second region 20, and the third region 30 are described herein.

The second grating layer 321 may include second grating structures 322A in which the third refractive index regions 321A and the fourth refractive index regions 321B are alternately arranged. The second grating layer 321 may include the second non-grating structure 322B which transmits a light beam reflected by the second grating structure 322A. Here, the second non-grating structure 322B may be formed of the fourth refractive index region 321B, but may be formed of the third refractive index region 321A. The second grating structures 322A may be arranged in the first region 10 and the second region 20. The second non-grating structure 322B may be arranged in the third region 30. The second grating structures 322A may be arranged in a part of the third region 30.

The mesa structure 315 may have regions different in mesa width in the first direction D1. The semiconductor laser 301 may include the first region 10 having the first mesa width W1 and the second region 20 having the mesa width of the second mesa width W2. In the third example implementation, the first mesa width W1 may be wider than the second mesa width W2. That is, the mesa structure in the first reflection region 361 may be wider in mesa width than the mesa structure in the second reflection region 362. Moreover, the mesa structure 315 may include the third region 30 which may be between the first region 10 and the second region 20, and in which the mesa width gradually changes from the first mesa width W1 to the second mesa width W2. It may be desired that the third region 30 be in a tapered shape having a mesa width gradually changing from the first region 10 toward the second region 20. However, boundaries between the third region 30 and the buried layer 17 may change linearly or may change while including a curve in top view. The second electrode 3 may be integrally arranged across the first region 10, the second region 20, and the third region 30. The second electrode 3 may be individually arranged in each region, but in this case, it may be desired that each of the individually arranged electrodes be connected to the same power supply.

The semiconductor laser 301 may include the first reflection region 361, the second reflection region 362, and a phase shift region 363 as in the first example implementation. The first reflection region 361 may be arranged in the first region 10, and may include the first grating structure 312A of the first grating layer 311 and the second grating structure 322A of the second grating layer 321. Here, the first grating structure 312A and the second grating structure 322A may be arranged such that the periods and the center positions in the first direction DI are the same as in the first example implementation. The second reflection region 362 may be arranged in the second region 20, and may include the first non-grating structure 312B of the first grating layer 311 and the second grating structure 322A of the second grating layer 321. The phase shift region 363 may include the first non-grating structure 312B of the first grating layer 311 and the second non-grating structure 322B of the second grating layer 321. When the second grating structure 322A is arranged in the third region 30, a region thereof may be included in the first reflection region 361 or the second reflection region 362.

As in the first example implementation, the period of the second grating structure 322A in the first reflection region 361 and the period of the second grating structure 322A in the second reflection region 62 may be the same. Moreover, the phases may be x-shifted from each other in consideration of optical path lengths of the mutual grating structures. The first reflection region 361 may have two stages of the grating structure, and the second reflection region 362 may have one stage thereof. Thus, the first reflection region 61 may be larger in coupling coefficient κ. Moreover, κ1L1 of the first reflection region 361 may be larger than κ2L2 of the second reflection region 362. Thus, the light intensity output from the front facet 40 may be higher than the light intensity output from the rear facet 50 as in the first example implementation.

In the third example implementation, in the first grating layer 311 of the first region 10, the first refractive index regions 311A and the second refractive index regions 311B may be arranged. Meanwhile, in the first grating layer 311 of the second region 20, only the first refractive index region 311A may be arranged. Here, the refractive index of the first refractive index region 311A may be larger than that of the second refractive index region 311B. Thus, when the comparison is made in terms of only the first grating layer 311, the effective refractive index of the second region 20 may be higher than that of the first region 10. Moreover, the second grating layer 321 of the first region 10 and the second region 20 may be the same second grating structures 322A. Here, when the comparison is made in terms of only the second grating layer 321, the effective refractive indices of the first region 10 and the second region 20 may be the same. The first region 10 and the second region 20 may be the same in the remaining semiconductor multilayer structures. As a result, for the same mesa width, the effective refractive index of the first region 10 may be lower than the effective refractive index of the second region 20. As in the first example implementation, in order to make the periods of the grating structures of the first reflection region 361 and the second reflection region 362 the same, it may be required that the effective refractive indices of the first region 10 and the second region 20 be substantially the same. Thus, in the third example implementation, the first mesa width W1 of the first region 10 may be wider than the second mesa width W2 of the second region 20.

As described above, the high single mode oscillation may be achieved while the same periods of the grating structures may be maintained by adjusting the mesa widths in accordance with the grating structures included in the first reflection region 361 and the second reflection region 362.

The present invention is not limited to the above-mentioned embodiments, and various modifications may be made thereto. For example, the configuration described in the embodiments may be replaced by substantially the same configuration, a configuration having the same action and effect, or a configuration that can achieve the same object. Moreover, the present invention is not limited to a buried type semiconductor laser, and is applicable to a ridge waveguide semiconductor laser as well. The semiconductor laser may be a CW light source or a direct-modulation laser. Moreover, in the first example implementation to the third example implementation, the examples in which two grating layers are included are given, but the number of grating layers may be three or more. Even when the number of grating layers is three or more, the light output intensity from the front facet may be increased by setting the normalized coupling coefficient of the first region to be higher than the normalized coupling coefficient of the second region.

The present invention is excellent in the high output characteristic, the high single mode oscillation, and the manufacturability in the semiconductor laser having the mesa structure. The example implementations of the present invention achieve this effect by arranging the two layers of grating layers, making the periods of the grating structures included in the first reflection region included in the first region and in the second reflection region included in the second region the same, and differentiating the mesa widths of the first reflection region and the second reflection region from each other, to thereby achieve substantially the same effective refractive indices both thereof. Moreover, the normalized coupling coefficient of the first reflection region may be larger than the normalized coupling coefficient of the second reflection region. The phases of the grating structures in consideration of the mutual optical path lengths of the first reflection region and the second reflection region may be x-shifted from each other. The first reflection region may include the second grating structure included in the second grating layer arranged on the farther side from the active layer. The second reflection region may include any one of the first grating structure included in the first grating layer arranged on the closer side from the active layer or the second grating structure. For example, the first reflection region may have two stages of the grating structures of the first grating structure and the second grating structure, and the second reflection region may have only one stage of the grating structure of the first grating structure. As another example, the first reflection region may have the first non-grating structure which may be included in the first grating layer and does not reflect the light beam and the second grating structure, and the second reflection region may have only the first grating structure. In those two examples, the second grating layer may be thicker than the first grating layer in the stacking direction. Moreover, the mesa width of the first region including the first reflection region may be narrower than the mesa width of the second region including the second reflection region. As an example different therefrom, the first reflection region may have two stages of the grating structures of the first grating structure and the second grating structure, and the second reflection region may have the first non-grating structure and the second grating structure. In this example, the second grating layer may be thinner than the first grating layer in the stacking direction. Moreover, the mesa width of the first region including the first reflection region may be wider than the mesa width of the second region including the second reflection region. Moreover, the semiconductor laser may include the phase shift region between the first reflection region and the second reflection region. The phase shift region may include the phase shift portion, and may may have the structure without including the grating structure.

In a first implementation, there is provided a semiconductor laser including: a substrate; an active layer arranged on the substrate; a cladding layer arranged on the active layer, the cladding layer including a first grating layer at least a part of which has a first grating structure, and a second grating layer which is arranged above and apart from at least the part of the first grating layer and at least a part of which has a second grating structure; and an electrode arranged on the cladding layer; wherein the active layer and the cladding layer form a mesa structure, wherein the mesa structure includes a first reflection region and a second reflection region that form a resonator in a direction in which the mesa structure extends, wherein the second grating structure is formed in the first reflection region, wherein any one of the first grating structure or the second grating structure is formed in the second reflection region, wherein the first grating structure and the second grating structure are formed such that a normalized coupling coefficient of the first reflection region is larger than a normalized coupling coefficient of the second reflection region, and wherein the mesa structure in each of the first reflection region and the second reflection region has a mesa width varying in accordance with a refractive index.

In a second implementation, alone or in combination with the first implementation, the first grating structure is further formed in the first reflection region.

In a third implementation, alone or in combination with one or more of the first and second implementations, the second grating layer is thicker than the first grating layer, and the first grating structure is formed in the second reflection region.

In a fourth implementation, alone or in combination with one or more of the first through third implementations, the second grating structure included in the first reflection region and one of the first grating structure or the second grating structure included in the second reflection region are the same in period.

In a fifth implementation, alone or in combination with one or more of the first through fourth implementations, the first reflection region and the second reflection region are substantially the same in effective refractive index.

In a sixth implementation, alone or in combination with one or more of the first through fifth implementations, the semiconductor laser further includes a phase shift region between the first reflection region and the second reflection region, wherein the second grating structure included in the first reflection region and one of the first grating structure or the second grating structure included in the second reflection region are x-shifted from each other in phase.

In a seventh implementation, alone or in combination with one or more of the first through sixth implementations, the first grating layer includes a first refractive index region and a second refractive index region different in refractive index from the first refractive index region, the first grating structure is a uniform grating structure in which the first refractive index region and the second refractive index region are alternately and periodically arranged, the second grating layer includes a third refractive index region and a fourth refractive index region different in refractive index from the third refractive index region, and the second grating structure is a uniform grating structure in which the third refractive index region and the fourth refractive index region are alternately and periodically arranged.

In an eighth implementation, alone or in combination with one or more of the first through seventh implementations, the semiconductor laser further includes a phase shift portion in the phase shift region, wherein the phase shift portion is a structure in which one of the first refractive index region or the second refractive index region is continuously arranged.

In a ninth implementation, alone or in combination with one or more of the first through eighth implementations, the second grating layer has a second non-grating structure, the first grating structure and the second non-grating structure are formed in the second reflection region, and the second non-grating structure transmits a light beam reflected by the second grating structure.

In a tenth implementation, alone or in combination with one or more of the first through ninth implementations, the first grating structure and the second grating structure formed in the first reflection region are arranged at the same period and in the same phase.

In an eleventh implementation, alone or in combination with one or more of the first through tenth implementations, the mesa structure in the first reflection region is narrower in mesa width than the mesa structure in the second reflection region.

In a twelfth implementation, alone or in combination with one or more of the first through eleventh implementations, the first grating layer has a first non-grating structure, the second grating layer has a second non-grating structure, the first non-grating structure is formed in the first reflection region, the second non-grating structure is formed in the second reflection region, the first non-grating structure transmits a light beam reflected by the first grating structure, and the second non-grating structure transmits a light beam reflected by the second grating structure.

In a thirteenth implementation, alone or in combination with one or more of the first through twelfth implementations, the first grating layer includes a first refractive index region and a second refractive index region different in refractive index from the first refractive index region, the second refractive index region is formed of the cladding layer, the first non-grating structure in the first reflection region is formed of the first refractive index region, and the first grating structure in the second reflection region is a uniform grating structure in which the first refractive index region and the second refractive index region are alternately and periodically arranged.

In a fourteenth implementation, alone or in combination with one or more of the first through thirteenth implementations, the mesa structure in the first reflection region is narrower in mesa width than the mesa structure in the second reflection region.

In a fifteenth implementation, alone or in combination with one or more of the first through fourteenth implementations, the first non-grating structure in the first reflection region includes an uneven structure in a vicinity of a surface layer of the first non-grating structure, and the uneven structure is the same as the second grating structure in period.

In a sixteenth implementation, alone or in combination with one or more of the first through fifteenth implementations, the first grating layer has a first non-grating structure, the first non-grating structure and the second grating structure are formed in the second reflection region, and the first non-grating structure transmits a light beam reflected by the first grating structure.

In a seventeenth implementation, alone or in combination with one or more of the first through sixteenth implementations, the first grating layer includes a first refractive index region and a second refractive index region different in refractive index from the first refractive index region, the second refractive index region is formed of the cladding layer, the first non-grating structure in the second reflection region is formed of the first refractive index region, and the first grating structure in the first reflection region is a uniform grating structure in which the first refractive index region and the second refractive index region are alternately and periodically arranged.

In an eighteenth implementation, alone or in combination with one or more of the first through seventeenth implementations, the first grating layer is thicker than the second grating layer.

In a nineteenth implementation, alone or in combination with one or more of the first through eighteenth implementations, the mesa structure in the first reflection region is wider in mesa width than the mesa structure in the second reflection region.

In a twentieth implementation, alone or in combination with one or more of the first through nineteenth implementations, the semiconductor laser further includes a first facet; a second facet; and a spot size conversion region between the second facet and the second reflection region, wherein the first grating layer has a first non-grating structure, wherein the mesa width of the mesa structure in the spot size conversion region gradually decreases from the second reflection region toward the second facet, wherein the first non-grating structure and the second non-grating structure are formed in the spot size conversion region, wherein the first non-grating structure transmits a light beam reflected by the first grating structure, and wherein the second non-grating structure transmits a light beam reflected by the second grating structure.

While there have been described what are at present considered to be certain implementations of the invention, it will be understood that various modifications may be made thereto, and is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a substrate;
an active layer arranged on the substrate;
a cladding layer arranged on the active layer, the cladding layer including a first grating layer at least a part of which has a first grating structure, and a second grating layer which is arranged above and apart from at least the part of the first grating layer and at least a part of which has a second grating structure; and
an electrode arranged on the cladding layer;
wherein the active layer and the cladding layer form a mesa structure,
wherein the mesa structure includes a first reflection region and a second reflection region that form a resonator in a direction in which the mesa structure extends,
wherein the second grating structure is formed in the first reflection region,
wherein any one of the first grating structure or the second grating structure is formed in the second reflection region,
wherein the first grating structure and the second grating structure are formed such that a normalized coupling coefficient of the first reflection region is larger than a normalized coupling coefficient of the second reflection region, and
wherein the mesa structure in each of the first reflection region and the second reflection region has a mesa width varying in accordance with a refractive index.

2. The semiconductor laser according to claim 1, wherein the first grating structure is further formed in the first reflection region.

3. The semiconductor laser according to claim 1,
wherein the second grating layer is thicker than the first grating layer, and
wherein the first grating structure is formed in the second reflection region.

4. The semiconductor laser according to claim 1, wherein the second grating structure included in the first reflection region and one of the first grating structure or the second grating structure included in the second reflection region are the same in period.

5. The semiconductor laser according to claim 1, wherein the first reflection region and the second reflection region are substantially the same in effective refractive index.

6. The semiconductor laser according to claim 1, further comprising a phase shift region between the first reflection region and the second reflection region,
wherein the second grating structure included in the first reflection region and one of the first grating structure or the second grating structure included in the second reflection region are T-shifted from each other in phase.

7. The semiconductor laser according to claim 6,
wherein the first grating layer includes a first refractive index region and a second refractive index region different in refractive index from the first refractive index region,
wherein the first grating structure is a uniform grating structure in which the first refractive index region and the second refractive index region are alternately and periodically arranged,
wherein the second grating layer includes a third refractive index region and a fourth refractive index region different in refractive index from the third refractive index region, and
wherein the second grating structure is a uniform grating structure in which the third refractive index region and the fourth refractive index region are alternately and periodically arranged.

8. The semiconductor laser according to claim 7, further comprising a phase shift portion in the phase shift region,
wherein the phase shift portion is a structure in which one of the first refractive index region or the second refractive index region is continuously arranged.

9. The semiconductor laser according to claim 2,
wherein the second grating layer has a second non-grating structure,
wherein the first grating structure and the second non-grating structure are formed in the second reflection region, and
wherein the second non-grating structure transmits a light beam reflected by the second grating structure.

10. The semiconductor laser according to claim 9, wherein the first grating structure and the second grating structure formed in the first reflection region are arranged at the same period and in the same phase.

11. The semiconductor laser according to claim 9, wherein the mesa structure in the first reflection region is narrower in mesa width than the mesa structure in the second reflection region.

12. The semiconductor laser according to claim 3,
wherein the first grating layer has a first non-grating structure,
wherein the second grating layer has a second non-grating structure,
wherein the first non-grating structure is formed in the first reflection region,
wherein the second non-grating structure is formed in the second reflection region,
wherein the first non-grating structure transmits a light beam reflected by the first grating structure, and
wherein the second non-grating structure transmits a light beam reflected by the second grating structure.

13. The semiconductor laser according to claim 12,
wherein the first grating layer includes a first refractive index region and a second refractive index region different in refractive index from the first refractive index region,
wherein the second refractive index region is formed of the cladding layer,
wherein the first non-grating structure in the first reflection region is formed of the first refractive index region, and
wherein the first grating structure in the second reflection region is a uniform grating structure in which the first refractive index region and the second refractive index region are alternately and periodically arranged.

14. The semiconductor laser according to claim 12, wherein the mesa structure in the first reflection region is narrower in mesa width than the mesa structure in the second reflection region.

15. The semiconductor laser according to claim 13,
wherein the first non-grating structure in the first reflection region includes an uneven structure in a vicinity of a surface layer of the first non-grating structure, and
wherein the uneven structure is the same as the second grating structure in period.

16. The semiconductor laser according to claim 2,
wherein the first grating layer has a first non-grating structure,
wherein the first non-grating structure and the second grating structure are formed in the second reflection region, and
wherein the first non-grating structure transmits a light beam reflected by the first grating structure.

17. The semiconductor laser according to claim 16,
wherein the first grating layer includes a first refractive index region and a second refractive index region different in refractive index from the first refractive index region,
wherein the second refractive index region is formed of the cladding layer,
wherein the first non-grating structure in the second reflection region is formed of the first refractive index region, and
wherein the first grating structure in the first reflection region is a uniform grating structure in which the first refractive index region and the second refractive index region are alternately and periodically arranged.

18. The semiconductor laser according to claim 16, wherein the first grating layer is thicker than the second grating layer.

19. The semiconductor laser according to claim 16, wherein the mesa structure in the first reflection region is wider in mesa width than the mesa structure in the second reflection region.

20. The semiconductor laser according to claim 1, further comprising:
a first facet;
a second facet; and
a spot size conversion region between the second facet and the second reflection region,
wherein the first grating layer has a first non-grating structure,
wherein the mesa width of the mesa structure in the spot size conversion region gradually decreases from the second reflection region toward the second facet,
wherein the first non-grating structure and the second non-grating structure are formed in the spot size conversion region.
wherein the first non-grating structure transmits a light beam reflected by the first grating structure, and
wherein the second non-grating structure transmits a light beam reflected by the second grating structure.
